(19) United States
(12) Patent Application Publication
(10) Pub. No.: US 2024/0316892 A1
(43) Pub. Date: Sep. 26, 2024

(54) ATTACHMENT PRESSING APPARATUS AND METHOD OF MANUFACTURING DISPLAY DEVICE USING THE SAME

(71) Applicant: Samsung Display Co., Ltd., Yongin-si (KR)

(72) Inventors: Janghoon Park, Yongin-si (KR); Dongwook Kim, Yongin-si (KR); Yonghyun Kim, Yongin-si (KR); Seungho Myoung, Yongin-si (KR)

(73) Assignee: Samsung Display Co., Ltd., Yongin-si (KR)

(21) Appl. No.: 18/587,157

(22) Filed: Feb. 26, 2024

(30) Foreign Application Priority Data
Mar. 24, 2023 (KR) 10-2023-0039021
Mar. 30, 2023 (KR) 10-2023-0042246

(51) Int. Cl. B30B 15/04; B30B 15/00; B30B 15/06; B30B 15/28; H10K 59/12; H10K 71/50

(52) U.S. Cl. CPC B30B 15/041; B30B 15/0035; B30B 15/0094; B30B 15/062; B30B 15/287; H10K 59/1201; H10K 71/50

(57) ABSTRACT

Provided are an attachment pressing apparatus and a method of manufacturing a display device using the attachment pressing apparatus. The attachment pressing apparatus includes a body portion that is tubular and extends in a first direction, a wing portion connected to a side of the body portion in the first direction and extending in a second direction intersecting the first direction, a pressing portion penetrating the wing portion in an inner space of the body portion in the first direction and pressing an attachment, and a compression portion connecting another side of the body portion in the first direction and the pressing portion.

### CROSS-REFERENCE TO RELATED APPLICATION(S)

This application claims priority to and benefits of Korean Patent Application No. 10-2023-0039021 under 35 U.S.C. § 119, filed on Mar. 24, 2023, and Korean Patent Application No. 10-2023-0042246 under 35 U.S.C. § 119, filed on Mar. 30, 2023, in the Korean Intellectual Property Office (KIPO), the entire contents of which are incorporated herein by reference.

### BACKGROUND

### 1. Technical Field

Embodiments relate to an attachment pressing apparatus for attaching an attachment onto a member to which the attachment always adheres with a uniform pressing force, and a method of manufacturing a display device using the attachment pressing apparatus.

### 2. Description of the Related Art

Mobility-based electronic devices have become widely used. Not only compact electronic devices such as mobile phones, but also tablet personal computers (PCs) have become widely used as mobile electronic devices.

A mobile electronic device includes a display device to provide visual information, such as an image or a video, to a user to support various functions. Recently, as other components for driving a display device are miniaturized, it is a trend that a proportion taken by the display device in an electronic device is gradually increasing, and a structure that is bendable to a certain angle from a flat state has been developed.

In order to manufacture a display device, a process of transferring a display substrate by attaching the display substrate to a carrier may be performed multiple times. The display substrate may be attached to the carrier by an adhesive chuck and then transferred.

### SUMMARY

Embodiments include an attachment pressing apparatus that may attach an attachment in a simple manner and always with a uniform pressing force in case that the attachment, such as an adhesive chuck, is attached to a member, and a method of manufacturing a display device using the attachment pressing apparatus.

However, such an objective is an example, and the objectives to be solved by the disclosure are not limited thereto.

Additional aspects will be set forth in part in the description which follows and, in part, will be apparent from the description, or may be learned by practice of the presented embodiments of the disclosure.

According to an embodiment, an attachment pressing apparatus may include a body portion that is tubular and extends in a first direction, a wing portion connected to a side of the body portion in the first direction, a pressing portion penetrating the wing portion in an inner space of the body portion in the first direction and pressing an attachment, and a compression portion connecting another side of the body portion in the first direction and the pressing portion.

In an embodiment, in case that the wing portion moves toward the attachment, the compression portion may be compressed and transfer a compressive force to the pressing portion, and the pressing portion may press the attachment.

In an embodiment, the compression portion may include a compression spring.

In an embodiment, the wing portion may include a wing plate including a through-hole through which the pressing portion passes and extending in a second direction intersecting the first direction, and a leg extending from the wing plate to the attachment.

In an embodiment, the pressing portion may include a pressing surface contacting the attachment, and in case that the wing portion moves until an end portion of the leg is located on a same plane as the pressing surface, the compression portion may be compressed and press the pressing portion.

In an embodiment, the wing portion may further include a length adjustment portion for adjusting a length of the leg.

In an embodiment, in a plan view, a width of the wing plate in a direction may be greater than a width of the wing plate in another direction perpendicular to the direction.

In an embodiment, the wing portion may include a wing plate including a through-hole through which the pressing portion passes and extending in a second direction intersecting the first direction, and a sliding guide portion that is tubular and extends from the wing plate to the compression portion. The sliding guide portion may guide a movement of the wing portion along the pressing portion that is inserted to penetrate through a through-hole of the sliding guide portion.

In an embodiment, the pressing portion may include a pressing plate in contact with the attachment, a shaft connected to the pressing plate and penetrating the wing portion, and a restriction portion arranged in an end portion of the shaft. A diameter of the restriction portion may be greater than a diameter of the through-hole of the sliding guide portion.

In an embodiment, the attachment pressing apparatus may further include a measurement portion arranged at the another side of the body portion in the first direction, connected to the compression portion, and measuring a compressive force of the compression portion.

In an embodiment, the attachment pressing apparatus may further include a display portion arranged on an outer surface of the body portion and displaying the compressive force measured by the measurement portion.

According to an embodiment, an attachment pressing apparatus may include a first unit and a second unit. Each of the first unit and second unit may include a body portion that is tubular and extends in a first direction, a wing portion connected to a side of the body portion in the first direction, a pressing portion penetrating the wing portion in an inner space of the body portion in the first direction and pressing an attachment, and a compression portion connecting another side of the body portion in the first direction and the pressing portion. The wing portion of the first unit and the wing portion of the second unit may be connected to each other.

In an embodiment, in case that the wing portion moves toward the attachment, the compression portion may be compressed and transfer a compressive force to the pressing portion, and the pressing portion may press the attachment.

In an embodiment, the wing portion may include a wing plate including a through-hole through which the pressing portion passes and extending in a second direction intersecting the first direction, and a leg extending from the wing plate to the attachment. The wing plate of the first unit and the wing plate of the second unit may be connected to each other.

In an embodiment, the wing plate may include a protruding portion protruding from a side of the wing plate, and a concave recess portion arranged at another side of the wing plate and corresponding to a shape of the protruding portion.

In an embodiment, the pressing portion may include a pressing surface contacting the attachment, and in case that the wing portion moves until an end portion of the leg is located on a same plane as the pressing surface, the compression portion may be compressed and press the pressing portion.

In an embodiment, the wing portion may further include a length adjustment portion for adjusting a length of the leg.

According to an embodiment, a method of manufacturing a display device may include attaching an adhesive chuck to a carrier by using an attachment pressing apparatus, seating a display substrate on the carrier on which the adhesive chuck adheres, and transferring a display substrate to a deposition device as the carrier moves. The attachment pressing apparatus may include a body portion that is tubular and extends in a first direction, a wing portion connected to a side of the body portion in the first direction and extending in a second direction intersecting the first direction, a pressing portion penetrating the wing portion in an inner space of the body portion in the first direction and pressing the adhesive chuck, and a compression portion connecting another side of the body portion in the first direction and the pressing portion.

Other aspects, features, and advantages than those described above will become apparent from the following drawings, claims, and detailed description of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display device according to an embodiment;

FIG. 2 is a schematic cross-sectional view of a display device according to an embodiment, which may correspond to a cross-section view of the display device taken along line II-II′ of FIG. 1;

FIG. 3 is a schematic cross-sectional view of an apparatus for manufacturing a display device, according to an embodiment;

FIG. 4 is a schematic perspective view of an attachment pressing apparatus according to an embodiment;

FIG. 5 is a schematic exploded perspective view of an attachment pressing apparatus according to an embodiment;

FIG. 6 is a view schematically illustrating the operation of an attachment pressing apparatus according to an embodiment;

FIG. 7 is a schematic cross-sectional view of an attachment pressing apparatus according to an embodiment; and

FIG. 8 is a schematic cross-sectional view of an attachment pressing apparatus according to an embodiment.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Various modifications may be applied to the embodiments, and particular embodiments will be illustrated in the drawings and described in the detailed description section. The effect and features of the embodiments, and a method to achieve the same, will be clearer referring to the detailed descriptions below with the drawings. However, the embodiments may be implemented in various forms, not by being limited to the embodiments presented below.

Hereinafter, embodiments will be described in detail with reference to the accompanying drawings, and in the description with reference to the drawings, the same or corresponding constituents are indicated by the same reference numerals and redundant descriptions thereof are omitted.

In the following embodiment, it will be understood that although the terms first, second, etc. may be used herein to describe various elements, these elements should not be limited by these terms. These elements are only used to distinguish one element from another.

In the following embodiment, as used herein, the singular forms “a,” “an,” and “the” are intended to include the plural forms as well, unless the context clearly indicates otherwise.

In the following embodiment, it will be further understood that the terms “comprises” and/or “comprising” used herein specify the presence of stated features or elements, but do not preclude the presence or addition of one or more other features or components.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Sizes of elements in the drawings may be exaggerated for convenience of explanation. For example, since sizes and thicknesses of elements in the drawings are arbitrarily illustrated for convenience of explanation, the following embodiments are not limited thereto.

In the following embodiment, the X-axis, the Y-axis, and the Z-axis are not limited to three axes of the rectangular coordinate system, and may be interpreted in a broader sense. For example, the X-axis, the Y-axis, and the Z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

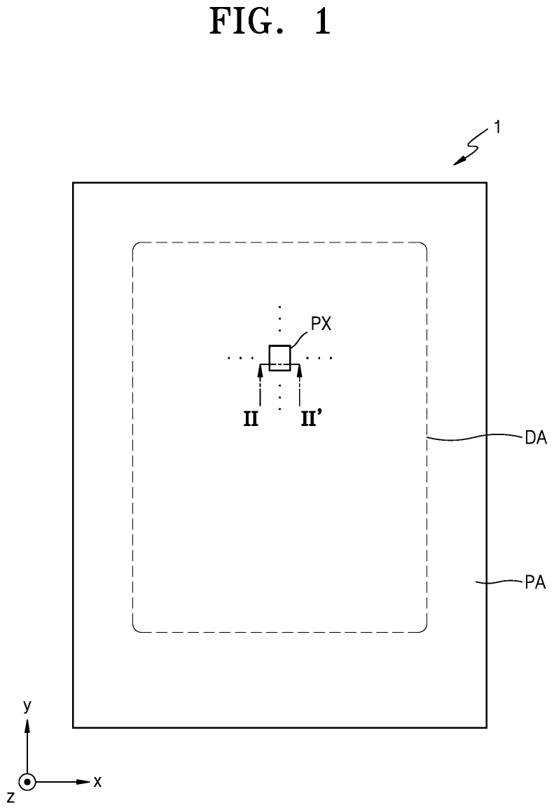

FIG. 1 is a schematic plan view of a display device 1 according to an embodiment.

Referring to FIG. 1, the display device 1 may include a display area DA and a peripheral area PA arranged adjacent to the display area DA. The display device 1 may provide an image through an array of multiple pixels PX two-dimensionally arranged in the display area DA.

The peripheral area PA, which is an area that does not provide an image, may entirely or partially surround the display area DA. Drivers and the like for providing electrical signals or power to a pixel circuit corresponding to each of the pixels PX may be arranged in the peripheral area PA. A pad that is an area to which electronic elements, a printed circuit board, and the like may be electrically connected may be arranged in the peripheral area PA.

Although the following description illustrates that the display device 1 includes an organic light-emitting diode (OLED) as a light-emitting element, the disclosure is not limited thereto. In another embodiment, the display device 1 may be a light-emitting display device including an inorganic light-emitting diode, for example, an inorganic light-emitting display device. The inorganic light-emitting diode may include a PN diode including inorganic semiconductor-based materials. In case that a voltage is applied to a PN junction diode in the forward direction, holes and electrons may be injected, and the energy generated by recombination of the holes and electrons may be converted into light energy so that light of a certain color may be emitted. The inorganic light-emitting diode described above may have a width of several to hundreds of micrometers, and in embodiments, the inorganic light-emitting diode may be a micro LED. In another embodiment, the display device 1 may include a quantum-dot light-emitting display device.

The display device 1 may be used as a display screen of not only a portable electronic device, such as a mobile phone, a smart phone, a tablet personal computer (PC), a mobile communication terminal, an electronic organizer, an electronic book, a portable multimedia player (PMP), a navigation device, an ultra-mobile PC (UMPC), and the like, but also various products, such as a television, a notebook computer, a monitor, a billboard, internet of things (IoT) device, and the like. Furthermore, the display device 1 according to an embodiment may be used for a wearable device, such as a smart watch, a watch phone, a glasses-type display, and a head mounted display (HMD). Furthermore, the display device 1 according to an embodiment may be used as an instrument panel of a vehicle, a center information display (CID) disposed in the center fascia or dashboard of a vehicle, a room mirror display in lieu of a side mirror of a vehicle, or a display screen disposed at the rear surface of a front seat as an entertainment device for a rear seat of a vehicle.

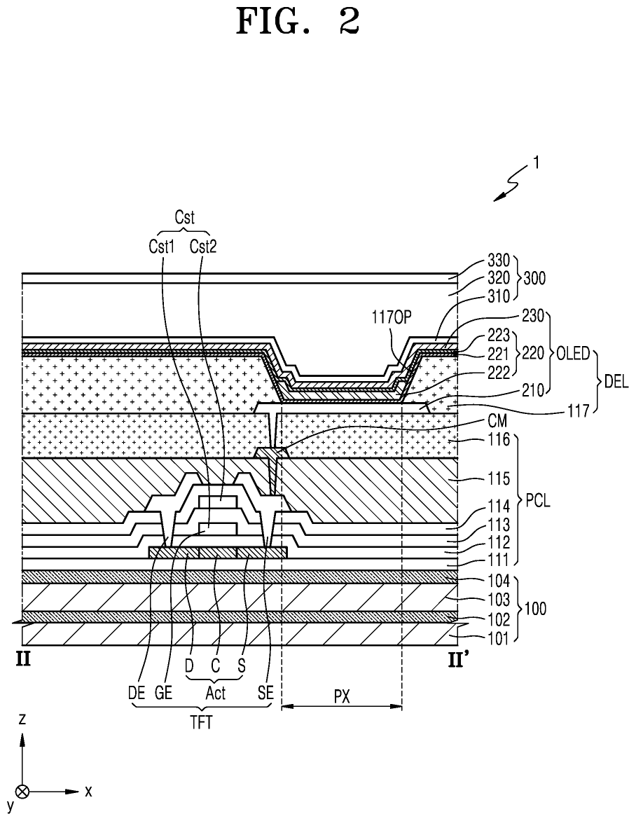

FIG. 2 is a schematic cross-sectional view of a display device according to an embodiment, which may correspond to a cross-section of the display device 1 taken along line II-II′ of FIG. 1.

Referring to FIG. 2, the display device 1 may include a stack structure of a substrate 100, a pixel circuit layer PCL, a display element layer DEL, and an encapsulation layer 300.

The substrate 100 may have a multilayer structure including a base layer including a polymer resin and an inorganic layer. For example, the substrate 100 may include a base layer including a polymer resin and a barrier layer of an inorganic insulating layer. For example, the substrate 100 may include a first base layer 101, a first barrier layer 102, a second base layer 103, and a second barrier layer 104, which are sequentially stacked. The first base layer 101 and the second base layer 103 may include polyimide (PI), polyethersulfone (PES), polyarylate, polyetherimide (PEI), polyethylene naphthalate (PEN), polyethylene terephthalate (PET), polyphenylene sulfide (PPS), polycarbonate (PC), cellulose triacetate (TAC), cellulose acetate propionate (CAP), or/and the like. The first barrier layer 102 and the second barrier layer 104 may include an inorganic insulating material, such as a silicon oxide, a silicon oxynitride, and/or a silicon nitride. The substrate 100 may be flexible.

The pixel circuit layer PCL may be disposed on the substrate 100. FIG. 2 illustrates that the pixel circuit layer PCL includes a thin film transistor TFT, and a buffer layer 111, a first gate insulating layer 112, a second gate insulating layer 113, an interlayer insulating layer 114, a first planarization insulating layer 115, and a second planarization insulating layer 116, which are arranged below or/and above constituent elements of the thin film transistor TFT.

The buffer layer 111 may reduce or block infiltration of foreign materials, moisture, or external air from under the substrate 100, and provide a planarized surface on the substrate 100. The buffer layer 111 may include an inorganic insulating material, such as a silicon oxide, a silicon oxynitride, and a silicon nitride, and have a single layer or multilayer structure including the material described above.

The thin film transistor TFT of the buffer layer 111 may include a semiconductor layer Act, and the semiconductor layer Act may include polysilicon. In another embodiment, the semiconductor layer Act may include amorphous silicon, oxide semiconductor, organic semiconductor, or the like. The semiconductor layer Act may include a channel region C and a drain region D and a source region S arranged at opposite sides of the channel region C. A gate electrode GE may overlap the channel region C in a plan view.

The gate electrode GE may include a low-resistance metal material. The gate electrode GE may include a conductive material such as molybdenum (Mo), aluminum (AI), copper (Cu), titanium (Ti), and the like, and may be formed in a multilayer or single layer including the material described above.

The first gate insulating layer 112 between the semiconductor layer Act and the gate electrode GE may include an inorganic insulating material, such as a silicon oxide (SiO₂), a silicon nitride (SiN_{X}), a silicon oxynitride (SiON), an aluminum oxide (Al₂O₃), a titanium oxide (TiO₂), tantalum oxide (Ta₂O₅), hafnium oxide (HfO₂), zinc oxide (ZnO_{X}), or the like. ZnO_{X} may be a zinc oxide (ZnO) and/or a zinc peroxide (ZnO₂).

The second gate insulating layer 113 may be provided to cover the gate electrode GE. The second gate insulating layer 113, similarly to the first gate insulating layer 112, may include an inorganic insulating material, such as SiO₂, SiN_{X}, SiON, Al₂O₃, TiO₂, Ta₂O₅, HfO₂, ZnO_{X}, or the like. ZnO_{X} may be ZnO, and/or ZnO₂.

An upper electrode Cst2 of a storage capacitor Cst may be disposed above the second gate insulating layer 113. The upper electrode Cst2 may overlap the gate electrode GE in a plan view. The gate electrode GE and the upper electrode Cst2, which overlap each other with the second gate insulating layer 113 interposed between the gate electrode GE and the upper electrode Cst2, may form a storage capacitor Cst. In other words, the gate electrode GE may function as a lower electrode Cst1 of the storage capacitor Cst.

As such, the storage capacitor Cst and the thin film transistor TFT may be formed to overlap each other in a plan view. In embodiments, the storage capacitor Cst may not be formed to overlap the thin film transistor TFT in a plan view.

The upper electrode Cst2 may include Al, platinum (Pt), palladium (Pd), silver (Ag), magnesium (Mg), gold (Au), nickel (Ni), neodymium (Nd), iridium (Ir), chromium (Cr), calcium (Ca), Mo, Ti, tungsten (W), and/or Cu, and may be formed in a single layer or multilayer including the material described above.

The interlayer insulating layer 114 may cover the upper electrode Cst2. The interlayer insulating layer 114 may include SiO₂, SiN_{X}, SiON, Al₂O₃, TiO₂, Ta₂O₅, HfO₂, ZnO_{X}, or the like. ZnO_{X} may be ZnO and/or ZnO₂. The interlayer insulating layer 114 may be a single layer or multilayer including the inorganic insulating material described above.

A drain electrode DE and a source electrode SE may each be located on the interlayer insulating layer 114. The drain electrode DE and the source electrode SE may be respectively connected to the drain region D and the source region S through contact holes formed in insulating layers. The drain electrode DE and the source electrode SE may each include a material having excellent conductivity. The drain electrode DE and the source electrode SE may each include a conductive material such as Mo, Al, Cu, Ti, and the like, and may be formed in a multilayer or single layer including the material described above. In an embodiment, the drain electrode DE and the source electrode SE may have a multilayer structure of Ti/AI/Ti.

The first planarization insulating layer 115 may cover the drain electrode DE and the source electrode SE. The first planarization insulating layer 115 may include an organic insulating materials, such as a general purpose polymer, such as polymethylmethacrylate (PMMA) or polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, and blends thereof.

The second planarization insulating layer 116 may be disposed on the first planarization insulating layer 115. The second planarization insulating layer 116 and the first planarization insulating layer 115 may include a same material.

The display element layer DEL may be disposed on the pixel circuit layer PCL. The display element layer DEL, as a display element, for example, a light-emitting element, may include an organic light-emitting diode OLED, and the organic light-emitting diode OLED may have a stack structure of a pixel electrode 210, an intermediate layer 220, and a common electrode 230. The organic light-emitting diode OLED may emit, for example, red, green, or blue light, or red, green, blue, or white light. The organic light-emitting diode OLED may emit light through an emission area, and the emission area may be defined as a pixel PX.

The pixel electrode 210 of the organic light-emitting diode OLED may be electrically connected to the thin film transistor TFT through contact holes formed in the second planarization insulating layer 116 and the first planarization insulating layer 115 and a contact metal CM arranged on the first planarization insulating layer 115.

The pixel electrode 210 may include a conductive oxide, such as an indium tin oxide (ITO), an indium zinc oxide (IZO), a zinc oxide (ZnO), an indium oxide (In₂O₃), an indium gallium oxide (IGO), or an aluminum zinc oxide (AZO). In another embodiment, the pixel electrode 210 may include a reflective film including Ag, Mg, Al, Pt, Pd, Au, Ni, Nd, Ir, Cr, or a compound thereof. In an embodiment, the pixel electrode 210 may further include a film formed of ITO, IZO, ZnO, or In₂O₃ above/below the reflective film described above.

A pixel defining layer 117 having an opening 1170P for exposing a central portion of the pixel electrode 210 may be disposed on the pixel electrode 210. The pixel defining layer 117 may include an organic insulating material and/or an inorganic insulating material. The opening 1170P may define the emission area of the light emitted from the organic light-emitting diode OLED. For example, the size/width of the opening 1170P may correspond to the size/width of the emission area in a plan view. Accordingly, the size and/or width of the pixel PX may be dependent on the size and/or width of the opening 117OP of the pixel defining layer 117 corresponding thereto.

The intermediate layer 220 may include an emission layer 222 formed to correspond to the pixel electrode 210. The emission layer 222 may include a polymer or low molecular weight organic material for emitting light of a certain color. In another embodiment, the emission layer 222 may include an inorganic light-emitting material or quantum dots.

In an embodiment, the intermediate layer 220 may include a first function layer 221 and a second function layer 223, which are respectively disposed below and above the emission layer 222. The first function layer 221 may include, for example, a hole transport layer (HTL), or the HTL and a hole injection layer (HIL). The second function layer 223 may include an electron transport layer (ETL) and/or an electron injection layer (EIL). The first function layer 221 and/or the second function layer 223 may be common layers formed to entirely cover the substrate 100, similar to the common electrode 230 described below.

The common electrode 230 may be disposed on the pixel electrode 210, and may overlap the pixel electrode 210 in a plan view. The common electrode 230 may include a conductive material having a low work function. For example, the common electrode 230 may include a (semi-)transparent layer including Ag, Mg, Al, Pt, Pd, Au, Ni, Nd, Ir, Cr, lithium (Li), Ca, the like, or an alloy thereof. In an embodiment, the common electrode 230 may further include a layer including ITO, IZO, ZnO, or In₂O₃ on the (semi-)transparent layer. The common electrode 230 may be integrally formed to entirely cover the substrate 100.

The encapsulation layer 300 may be disposed on the display element layer DEL and may cover the display element layer DEL. The encapsulation layer 300 may include at least one inorganic encapsulation layer and at least one organic encapsulation layer, and in an embodiment, the encapsulation layer 300 may include a first inorganic encapsulation layer 310, an organic encapsulation layer 320, and a second inorganic encapsulation layer 330, which are sequentially stacked on each other.

The first inorganic encapsulation layer 310 and the second inorganic encapsulation layer 330 may each include one or more inorganic materials including an aluminum oxide, a titanium oxide, a tantalum oxide, a hafnium oxide, a zinc oxide, a silicon oxide, a silicon nitride, a silicon oxynitride, or a combination thereof. The organic encapsulation layer 320 may include a polymer-based material such as an acrylic resin, an epoxy-based resin, polyimide, polyethylene, and the like. In an embodiment, the organic encapsulation layer 320 may include acrylate. The organic encapsulation layer 320 may be formed by hardening a monomer or applying a polymer. The organic encapsulation layer 320 may be transparent.

Although not illustrated, a touch sensor layer may be disposed on the encapsulation layer 300, and an optical function layer may be disposed on touch sensor layer. The touch sensor layer may obtain coordinate information according to an external input, for example, a touch event. The optical function layer may reduce reflectivity of light (external light) input toward the display device 1 from the outside, and/or improve color purity of the light emitted from the display device 1. In an embodiment, the optical function layer may include a retarder and/or a polarizer. The retarder may be of a film type or a liquid crystal coating type, and may include a λ/2 retarder and/or a λ/4 retarder. The polarizer may also be of a film type or a liquid crystal coating type. The film type may include a stretchable synthetic resin film, and the liquid crystal coating type may include liquid crystals oriented in an array. The retarder and the polarizer may each further include a protection film.

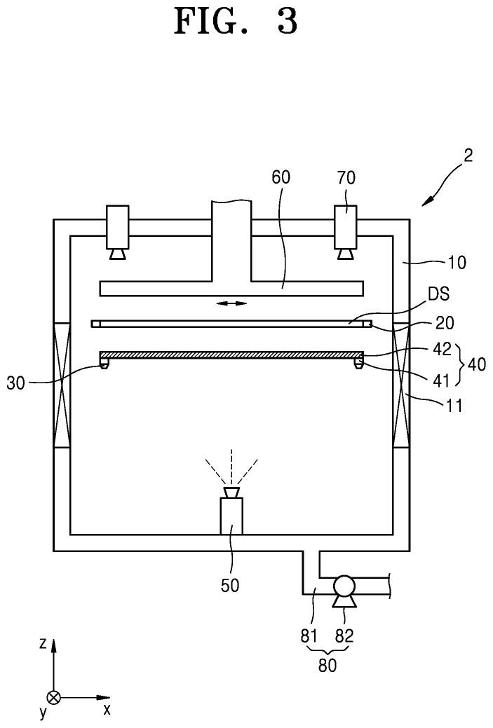

FIG. 3 is a schematic cross-sectional view of an apparatus 2 for manufacturing a display device, according to an embodiment.

Referring to FIG. 3, the apparatus 2 for manufacturing a display device may include a chamber 10, a first support portion 20, a second support portion 30, a mask assembly 40, a deposition source 50, a magnetic force portion 60, a vision portion 70, and a pressure regulation portion 80.

The chamber 10 may have a space formed therein, and a display substrate DS and a mask assembly 40 may be accommodated in the chamber 10. A part of the chamber 10 may be formed to be open, and a gate valve 11 may be installed in the open portion of the chamber 10. The open portion of the chamber 10 may be opened or closed depending on the operation of the gate valve 11.

The display substrate DS may be the display device 1 in the course of manufacturing, on which at least one of an organic layer, an inorganic layer, and a metal layer is deposed. In another embodiment, the display substrate DS may be the substrate 100 on which no layer of the organic layer, the inorganic layer, and the metal layer has been deposed.

The first support portion 20 may support the display substrate DS. The first support portion 20 may be in the form of a plate fixed in the chamber 10. In another embodiment, the first support portion 20 may be in the form of a shuttle on which the display substrate DS is seated, and capable of a linear motion inside the chamber 10. In another embodiment, the first support portion 20 may include an electrostatic chuck or an adhesive chuck, which is fixed to the chamber 10 or arranged to be movable inside the chamber 10.

The second support portion 30 may support the mask assembly 40. The second support portion 30 may be arranged in the chamber 10. The second support portion 30 may be capable of fine adjustment of the location of the mask assembly 40. The second support portion 30 may include a separate driving unit or alignment unit and the like to move the mask assembly 40 in a separate direction.

In another embodiment, the second support portion 30 may be in the form of a shuttle. The mask assembly 40 may be seated on the second support portion 30, and the second support portion 30 may transfer the mask assembly 40. For example, the second support portion 30 may move to the outside of the chamber 10 and have the mask assembly 40 seated thereon, and enter the inside of the chamber 10 from the outside of the chamber 10.

The first support portion 20 and the second support portion 30 may be integrally formed with each other. The first support portion 20 and the second support portion 30 may include a movable shuttle. The first support portion 20 and the second support portion 30 may each have a structure of fixing the mask assembly 40 and the display substrate DS while the display substrate DS is seated on the mask assembly 40, and may be capable of simultaneously linearly moving the display substrate DS and the mask assembly 40.

However, in the following description, for convenience of explanation, an embodiment in which the first support portion 20 and the second support portion 30 are separately formed and arranged at different positions, and the first support portion 20 and the second support portion 30 are arranged inside the chamber 10 is described in detail.

The deposition source 50 may be arranged to face the mask assembly 40. A deposition material may be accommodated in the deposition source 50, and by heating the deposition material, the deposition material may be evaporated or sublimated. The deposition source 50 may be arranged to be fixed inside the chamber 10 or arranged inside the chamber 10 to be capable of a linear motion in a direction.

The mask assembly 40 may be arranged in the chamber 10. The mask assembly 40 may include a mask frame 41 and a mask sheet 42. The deposition material may pass through the mask assembly 40 and deposited on the display substrate DS.

The magnetic force portion 60 may be arranged in the chamber 10 facing the display substrate DS and/or the mask assembly 40. The magnetic force portion 60 may apply a magnetic force to the mask assembly 40 to apply a force to the mask assembly 40 toward the display substrate DS. For example, the magnetic force portion 60 may not only prevent sagging of the mask sheet 42, but also move the mask sheet 42 close to the display substrate DS. Furthermore, the magnetic force portion 60 may maintain the interval between the mask sheet 42 and the display substrate DS uniform.

The vision portion 70 may be arranged in the chamber 10, and may photograph the positions of the display substrate DS and the mask assembly 40. The vision portion 70 may include a camera for capturing images of the display substrate DS and the mask assembly 40. The positions of the display substrate DS and the mask assembly 40 may be identified based on the images captured by the vision portion 70, and the deformation of the mask assembly 40 may be checked. Furthermore, based on the images, the first support portion 20 may finely adjust the position of the display substrate DS or the second support portion 30 may finely adjust the position of the mask assembly 40. However, in the following description, an embodiment in which the second support portion 30 finely adjusts the position of the mask assembly 40 to align the positions of the display substrate DS and the mask assembly 40 is described in detail.

The pressure regulation portion 80 may be connected to the chamber 10 to adjust the pressure inside the chamber 10. For example, the pressure regulation portion 80 may adjust the internal pressure of the chamber 10 to be the same as or similar to the atmospheric pressure. For example, the pressure regulation portion 80 may adjust the internal pressure of the chamber 10 to be the same as or similar to the vacuum state.

The pressure regulation portion 80 may include a connection pipe 81 connected to the chamber 10 and a pump 82 installed on the connection pipe 81. According to the operation of the pump 82, external air may be introduced into the chamber 10 through the connection pipe 81 or a gas in the chamber 10 may be exhausted to the outside through the connection pipe 81.

In a method of manufacturing a display device by using the apparatus 2 for manufacturing a display device configured as above, first, the display substrate DS may be prepared.

The pressure regulation portion 80 may maintain the inside of the chamber 10 to be the same as or similar to the atmospheric pressure, and as the gate valve 11 operates, the open portion of the chamber 10 may be opened.

The display substrate DS may be loaded into the chamber 10 from the outside. The display substrate DS may be loaded into the chamber 10 in various methods. For example, the display substrate DS may be loaded into the chamber 10 from the outside the chamber 10 through a carrier arranged outside the chamber 10. An adhesive chuck may be attached to the carrier, and the display substrate DS may be bonded to the carrier by using the adhesive chuck, and the display substrate DS may be loaded into the chamber 10. In an embodiment, the adhesive chuck may be attached to the carrier by using an attachment pressing apparatus 500 described below.

In another embodiment, in case that the first support portion 20 is in the form of a shuttle, the first support portion 20 may be carried from the inside of the chamber 10 to the outside of the chamber 10, the display substrate DS may be seated on the first support portion 20, and the first support portion 20 may be loaded into the chamber 10 from the outside. The display substrate DS may be attached and seated on the first support portion 20 by using an adhesive chuck. The adhesive chuck may be attached to the first support portion 20 by using an attachment pressing apparatus 500 described below.

The mask assembly 40 may be arranged in the chamber 10 as described above. In another embodiment, the mask assembly 40 may be loaded into the chamber 10 from the outside the chamber 10 in the same or similar manner as the display substrate DS.

In case that the display substrate DS is loaded into the chamber 10, the display substrate DS may be seated on the first support portion 20. The vision portion 70 may photograph the positions of the display substrate DS and the mask assembly 40. The positions of the display substrate DS and the mask assembly 40 may be identified based on the images captured by the vision portion 70. The apparatus 2 for manufacturing a display device may include a separate controller (not shown) to identify the positions of the display substrate DS and the mask assembly 40.

In case that the identification of the positions of the display substrate DS and the mask assembly 40 is completed, the second support portion 30 may finely adjust the position of the mask assembly 40.

As the deposition source 50 operates, the deposition material may be supplied toward the mask assembly 40, and the deposition material having passed through multiple opening portions of the mask sheet 42 may be deposited on the display substrate DS. The deposition source 50 may move in parallel to the display substrate DS and the mask assembly 40, or the display substrate DS and the mask assembly 40 may move in parallel to the deposition source 50. In other words, the deposition source 50 may move relative to the display substrate DS and the mask assembly 40. The pump 82 may suck the gas in the chamber 10 and discharge the gas to the outside so as to maintain the internal pressure of the chamber 10 in the same as or similar to the vacuum state.

As described above, the deposition material supplied from the deposition source 50 may pass through the mask assembly 40 and deposited on the display substrate DS, and thus, at least one of multiple layers, for example, an organic layer, an inorganic layer, and a metal layer, to be stacked on the display device described below may be formed.

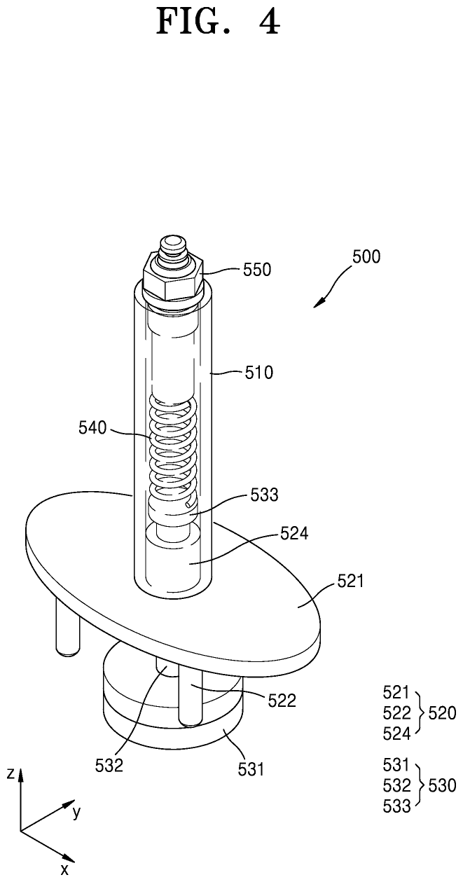

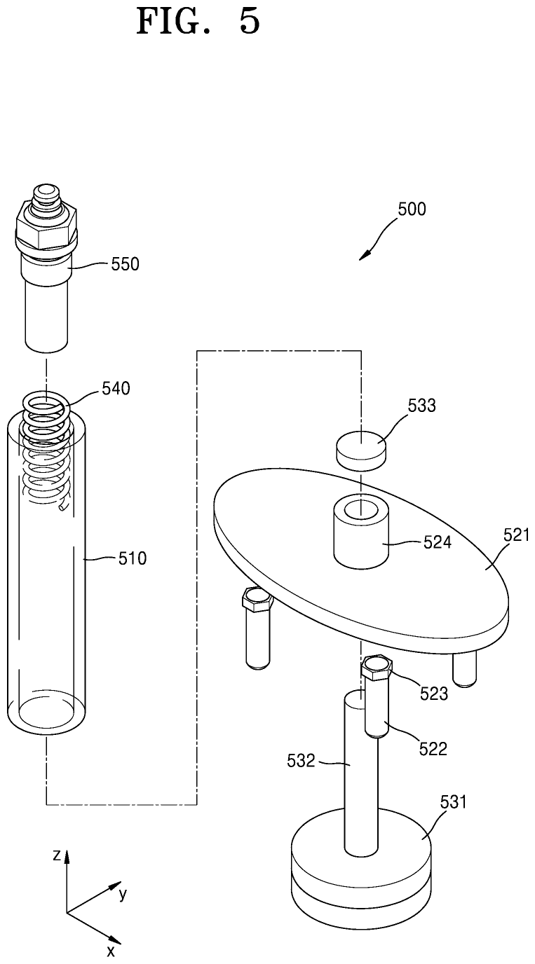

FIG. 4 is a schematic perspective view of an attachment pressing apparatus according to an embodiment. FIG. 5 is a schematic exploded perspective view of an attachment pressing apparatus according to an embodiment.

Referring to FIGS. 4 and 5, as described above, in the manufacturing process of a display device, the adhesive chuck may be attached to the carrier by using the attachment pressing apparatus 500, and the display substrate may be bonded to the carrier and transferred.

In other words, the attachment pressing apparatus 500 may be an apparatus to press an attachment to facilitate the attachment to a member to which the attachment adheres. In an embodiment, the member to which the attachment adheres may be a carrier for transferring and supporting a display substrate. In an embodiment, the attachment may be an adhesive chuck attached to the carrier to bond a substrate to the carrier. However, the disclosure is not limited to the deposition process described above, and the attachment pressing apparatus 500 may be used in various processes for bonding the display substrate DS to the carrier in the manufacturing process of a display device. The attachment pressing apparatus 500 may be used not only in the manufacturing process of a display device, but also in various fields to press an attachment.

The attachment pressing apparatus 500 may include a body portion 510, a wing portion 520, a pressing portion 530, a compression portion 540, and a measurement portion 550.

The body portion 510 may accommodate various members of the attachment pressing apparatus 500, and form the exterior of the attachment pressing apparatus 500. In an embodiment, the body portion 510 may be a tubular member extending in a first direction, for example, a z direction of FIG. 4. In an embodiment, the body portion 510 may be a cylinder having a space therein, but the disclosure is not limited thereto, and the body portion 510 may be a tubular member of a polygonal prism such as a square column having a space therein.

In an embodiment, the body portion 510 may include an opaque material. In another embodiment, the body portion 510 may include a transparent material so that components accommodated in the body portion 510 may be visible.

The wing portion 520 may be connected to an end portion of the body portion 510 in a length direction (for example, the first direction), and may be gripped to press the attachment pressing apparatus 500. In an embodiment, the wing portion 520 may include a wing plate 521, a leg 522, a length adjustment portion 523, and a sliding guide portion 524.

The wing plate 521 may be connected to an end portion of the body portion 510 in the length direction (for example, the first direction), and may protrude in a second direction, for example, an x direction of FIG. 4, intersecting the first direction. In other words, the wing plate 521 may be arranged to cover an open side of the body portion 510, and may have a cross-section greater than a cross-section of the body portion 510, in a plan view. In an embodiment, in a plan view, the wing plate 521 may have a width in the second direction that is greater than a width in a third direction, for example, a y direction of FIG. 4, intersecting the second direction. For example, the wing plate 521 may have an oval shape having a major axis in the second direction. However, the shape of the wing plate 521 is not limited to the oval shape, and may have various other shapes, for example, a shape in which the length protruding in the third direction is greater than the length protruding in the second direction. The shape of the wing plate 521 may be suitable to grip for pressing. In another embodiment, the wing plate 521 may have the same length protruding in the second direction and the third direction, like a circle.

In an embodiment, the wing plate 521 may include a through-hole (not shown). The through-hole may overlap the inner space of the body portion 510 of a tubular shape, and the inner space of the body portion 510 may communicate with the outside through the through-hole. In an embodiment, the through-hole may be formed at the center of the wing plate 521, in a plan view.

The leg 522 may be a shaft extending in a perpendicular direction from a surface of the wing plate 521. For example, the leg 522 may extend from the lower surface of the wing plate 521 toward the attachment, for example, in a −z direction of FIG. 4. In an embodiment, the leg 522 may include multiple legs, for example, two or more legs, for example, four or more legs. The legs 522 may be arranged to be horizontally and vertically symmetrical with respect to the center of the wing plate 521, in a plan view. For example, in case that the leg 522 includes four legs, the legs 522 may be arranged at the left upper end, the left lower end, the right upper end, and the right lower end with respect to the center of the wing plate 521.

The leg 522 may restrict the movement of the wing portion 520, as described below. For example, in case that the wing portion 520 moves toward the attachment, the leg 522 may move until contacting the ground (or an attachment surface). To this end, a distal end portion of the leg 522, for example, an end portion at a side opposite to the wing plate 521, may include rubber packing.

The length adjustment portion 523 may adjust the length of the leg 522 so that the movement amount of the wing portion 520 may be adjusted. In an embodiment, the length adjustment portion 523 may be arranged between the leg 522 and the wing plate 521. For example, the length adjustment portion 523 may be a nut arranged between the wing plate 521 and the leg 522. One or more nuts may be inserted between the wing plate 521 and the leg 522, and thus, the extended length of the leg 522 may be adjusted. However, the disclosure is not limited thereto, and the length adjustment portion 523 may employ various methods to adjust the extended length of the leg 522, for example, a rack-pinion gear.

The sliding guide portion 524 may guide the movement of the wing portion 520 along the pressing portion 530 described below. The sliding guide portion 524 may be a tubular member that extends from a surface of the wing plate 521 in the first direction, for example, the z direction of FIG. 4. In an embodiment, the sliding guide portion 524 may be cylindrical, but the disclosure is not limited thereto, and the sliding guide portion 524 may be a tubular member of a polygonal column such as a rectangular column. The sliding guide portion 524 and the body portion 510 may extend in a same direction, for example, in a direction opposite to the direction in which the leg 522 extends from the wing plate 521. The sliding guide portion 524 may be accommodated in the body portion 510, and may extend by a length corresponding to the length of the body portion 510. In an embodiment, the length of the sliding guide portion 524 may be less than or equal to about ½ of the length of the body portion 510.

The pressing portion 530 may contact the attachment and may press the attachment. In an embodiment, the pressing portion 530 may include a pressing plate 531, a shaft 532, and a restriction portion 533.

The pressing plate 531 may press the attachment to attach the attachment, for example, the adhesive chuck, to the carrier or susceptor. In an embodiment, the pressing plate 531 may be a circular plate, but the disclosure is not limited thereto, and the pressing plate 531 may employ various shapes to entirely cover the attachment along the shape of the attachment.

The shaft 532 may extend from the center of the pressing plate 531 in the first direction or the z direction of FIG. 4, for example, toward the body portion 510. The shaft 532 may pass through the through-hole of the wing plate 521 and penetrate through a through-hole of the sliding guide portion 524 that is tubular. Accordingly, a portion of the shaft 532 may be located in the body portion 510. The wing portion 520 may slidably move along the shaft 532.

The restriction portion 533 may be connected to an end portion of the shaft 532. In other words, the pressing plate 531 may be arranged in an end portion of the shaft 532, and the restriction portion 533 may be arranged in another end portion of the shaft 532. The diameter of the restriction portion 533 may be greater than the diameter of the shaft 532 and a diameter of the through-hole of the sliding guide portion 524. Accordingly, the upward movement of the wing portion 520 may be restricted as the end portion of the sliding guide portion 524 is caught by the restriction portion 533.

The compression portion 540 may be arranged in the inner space of the body portion 510, a side of the compression portion 540 may be fixed to the body portion 510, and another side of the compression portion 540 may be fixed to the pressing portion 530, for example, the restriction portion 533. In another embodiment, as described below, in case that the attachment pressing apparatus 500 includes the measurement portion 550, a side of the compression portion 540 may be fixed to the measurement portion 550 and another side of the compression portion 540 may be fixed to the pressing portion 530, for example, the restriction portion 533. In the following description, for convenience of explanation, as illustrated in FIGS. 4 and 5, an embodiment in which the compression portion 540 is located between the measurement portion 550 and the pressing portion 530 is described.

In an embodiment, the compression portion 540 may include an elastic material capable of compression and extension. For example, the compression portion 540 may be a coil-type compression spring. As described below, the compression portion 540 may be compressed or extended as the wing portion 520, the body portion 510 connected to the wing portion 520, and the measurement portion 550 fixed to the body portion 510 move. The compression portion 540, when compressed, may transfer energy to the pressing portion 530, for example, the restriction portion 533, and the energy may be used to press the attachment through the shaft 532 connected to the restriction portion 533, and the pressing plate 531.

Although FIG. 4 illustrates an embodiment in which the compression portion 540 is a coil-type compression spring, the disclosure is not limited thereto. For example, the compression portion 540 may be a compression spring in a different form such as a leaf type in which energy is stored when compressed. In another embodiment, the compression portion 540 may be a compression cylinder, for example, a pneumatic cylinder. As the wing portion 520, the body portion 510 connected to the wing portion 520, and the measurement portion 550 fixed to the body portion 510 move, the pneumatic cylinder may be compressed or extended. Accordingly, air in the compression portion 540, for example, a pneumatic cylinder, may be compressed so as to transfer a compressive force to the pressing portion 530, for example, the restriction portion 533.

The measurement portion 550 may measure a pressing force applied to the attachment by measuring the compressive force of the compression portion 540. The measurement portion 550 may be connected to an end portion of the body portion 510 in the length direction, for example, in the first direction or the z direction of FIG. 4, and may be arranged at the opposite side of the wing portion 520. For example, the wing portion 520 may be arranged in an end portion of the body portion 510 in the length direction, and the measurement portion 550 may be arranged in another end portion in the length direction. In an embodiment, the measurement portion 550 may include a force sensor, and measure the compressive force of the compression portion 540. Furthermore, as the compressive force of the compression portion 540 is the same as the pressing force pressing the attachment, the pressing force may be measured by the measurement portion 550. As such, the measured pressing force may be transmitted to a system (not shown) through a cable connected to the measurement portion 550. In an embodiment, the measured pressing force may be transmitted to and display on a display portion (not shown) that may be arranged on an external surface of the body portion 510.

The display portion may be a display screen for displaying an image. The display portion may output on a screen (not shown) a value of the pressing force input from the measurement portion 550.

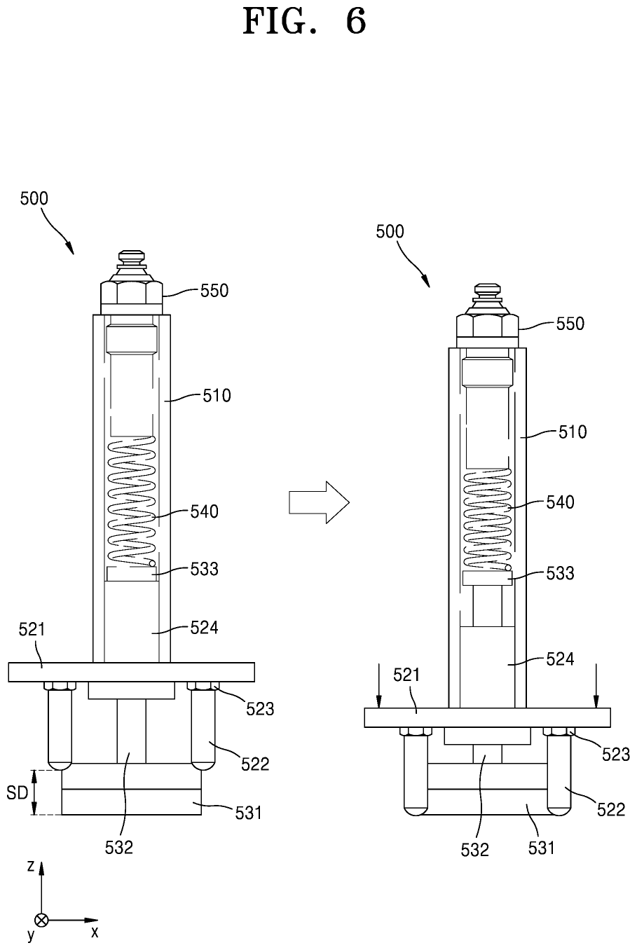

FIG. 6 is a view schematically illustrating the operation of the attachment pressing apparatus 500 according to an embodiment.

Referring to FIG. 6, the attachment pressing apparatus 500 may be arranged to attach an attachment to a member to which the attachment adheres. FIG. 6 illustrates a state in which an attachment is placed on a member to which the attachment adheres. To press the attachment, the attachment pressing apparatus 500, for example, the pressing plate 531, may contact the attachment. The wing portion 520 and the body portion 510 may be located at a first position. For example, the leg 522 may be in a state in which an end portion of the leg 522 is located at a position apart from a pressing surface (for example, a lower surface in FIG. 6) of the pressing plate 531. In other words, the end portion of the leg 522 may be located apart from the pressing surface of the pressing plate 531, by a separation distance SD. The sliding guide portion 524 of the wing portion 520 and the restriction portion 533 of the pressing portion 530 may be in contact with each other. The measurement portion 550 may measure a compressive force applied to the compression portion 540 to be 0. The compressive force applied to the compression portion 540 may be 0. In another embodiment, in case that a compressive force applied to the compression portion 540 is not 0, the compressive force may be defined to be 0 to be used as a reference value.

The wing portion 520 may be moved. Accordingly, the wing portion 520 and the body portion 510 may be moved to a second position. For example, by gripping the wing plate 521, the wing portion 520 may be moved downwardly in a direction toward the attachment. Accordingly, the wing portion 520, the body portion 510 connected to the wing portion 520, and the measurement portion 550 connected to the body portion 510 may all be moved downwardly toward the attachment. The wing portion 520 may be moved until the end portion of the leg 522 reaches the pressing surface of the pressing plate 531. In other words, the wing portion 520 may be moved by the separation distance SD and stopped in case that the leg 522 contacts a member to which the attachment adheres. The separation distance SD of the wing portion 520 may be set to a distance designed by a user by adjusting the length adjustment portion 523.

As the wing portion 520 moves, the body portion 510 and the measurement portion 550 connected to the body portion 510 may be moved together, and thus, the compression portion 540 may be compressed. The compression portion 540 may be compressed by the same length as the separation distance SD. Furthermore, as the compression portion 540 is compressed, the compressive force, for example, an elastic force, may be transferred to the restriction portion 533 and to the attachment through the pressing plate 531.

The attachment pressing apparatus 500 according to an embodiment may set a distance, for example, the separation distance SD, that the wing portion 520 is configured to travel, and may be moved until the leg 522 contacts the member to which the attachment adheres, for example, by the distance. Accordingly, the compression portion 540 may press the attachment by transferring the compressive force, for example, an elastic force, corresponding to the distance, to the pressing portion 530. Accordingly, the attachment pressing apparatus 500 may attach the attachment with the pressing force to the member. Furthermore, in case that multiple attachments are attached, the attachments may be attached with uniform force, thereby preventing defects due to over-adhesion or weak adhesion. Furthermore, the attachment pressing apparatus 500 may attach the attachment and simultaneously measure a pressing force with a measurement portion 550.

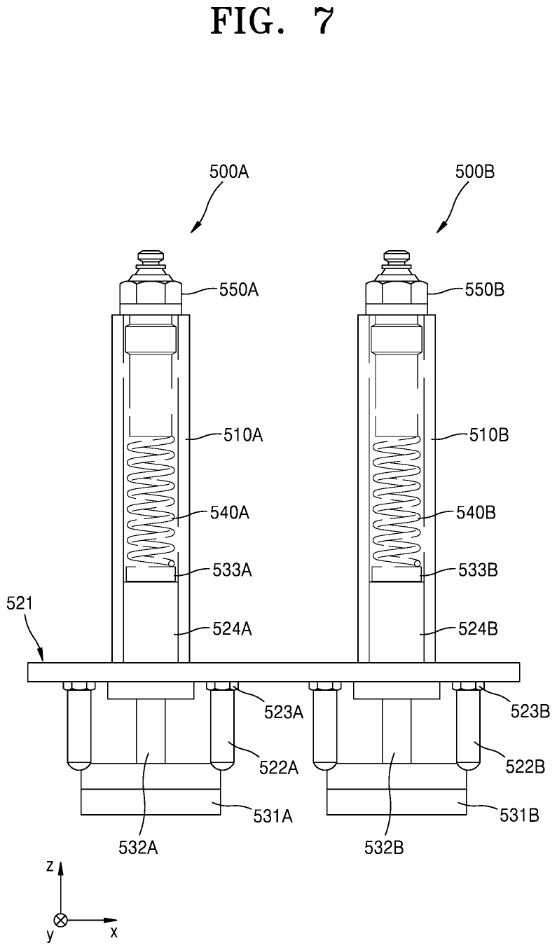

FIG. 7 is a schematic cross-sectional view of the attachment pressing apparatus 500 according to an embodiment. As the attachment pressing apparatus 500 described with reference to FIG. 7 is similar to the attachment pressing apparatus 500 described in FIGS. 4-6, only differences are described in the following description.

Referring to FIG. 7, the attachment pressing apparatus 500 may include multiple units, for example, a first unit 500A and a second unit 500B. Each of the first unit 500A and the second unit 500B may include the body portion 510, the wing portion 520, the pressing portion 530, the compression portion 540, and the measurement portion 550, similarly to the attachment pressing apparatus 500 described in FIG. 4. In other words, the first unit 500A may include a first body portion 510A, a first wing portion 520A, a first pressing portion 530A, a first compression portion 540A, and a first measurement portion 550A, and the second unit 500B may include a second body portion 510B, a second wing portion 520B, a second pressing portion 530B, a second compression portion 540B, and a second measurement portion 550B.

The first wing plate 521 of the first wing portion 520A and the second wing plate 521 of the second wing portion 520B may be integrally formed. In other words, the first unit 500A and the second unit 500B may be connected to each other by one wing plate 521. Furthermore, a first leg 522A of the first wing portion 520A and a second leg 522B of the second wing portion 520B may extend from the wing plate 521 and have a same length. Accordingly, in case that the first unit 500A and the second unit 500B move toward attachments by gripping the wing plate 521, the first unit 500A and the second unit 500B may be simultaneously operated and may simultaneously press the attachments.

The first measurement portion 550A and the second measurement portion 550B may respectively measure compressive forces from the first compression portion 540A and the second compression portion 540B and transmit the measured compressing forces to the system via a cable, and/or display the measured compressive forces on a first display portion (not shown) and a second display portion (not shown) respectively arranged in the first body portion 510A and the second body portion 510B.

The attachment pressing apparatus 500 as described above may simultaneously attach multiple attachments. Furthermore, the attachment pressing apparatus 500 may simultaneously attach multiple attachments with a same pressing force. Thus, the attachment process time of attachments may be reduced, and an attachment defect may be reduced.

Although FIG. 7 describes an embodiment in which the attachment pressing apparatus 500 includes two units, the disclosure is not limited thereto, and the attachment pressing apparatus 500 may include more than three units. In case that the attachment pressing apparatus 500 includes three or more units, in an embodiment, the units may be arranged in parallel in a direction, for example, an x direction of FIG. 7.

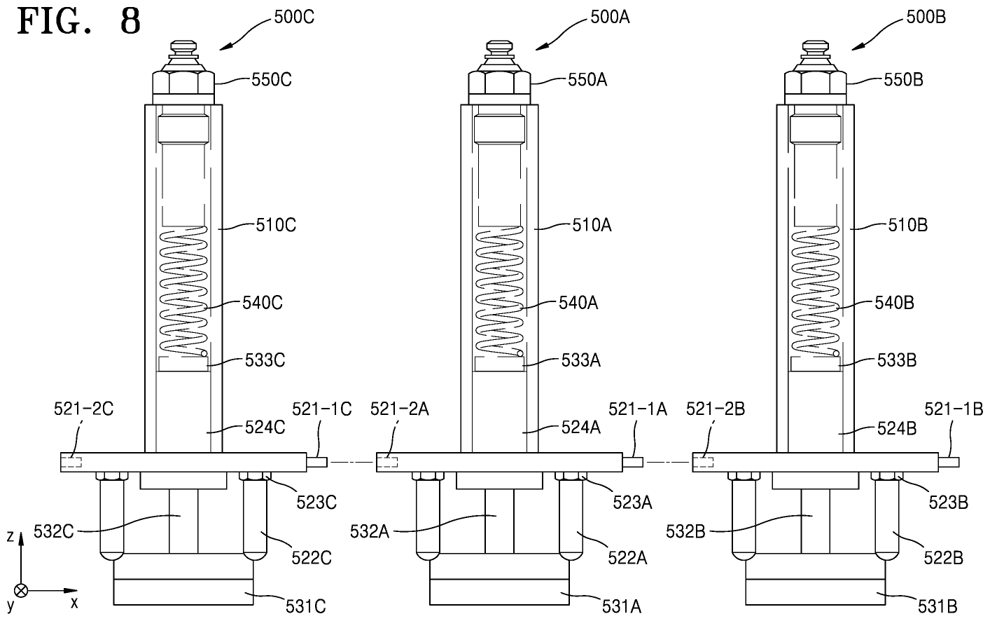

FIG. 8 is a schematic cross-sectional view of the attachment pressing apparatus 500 according to an embodiment. As the attachment pressing apparatus 500 described with reference to FIG. 8 is similar to the attachment pressing apparatus 500 described in FIGS. 4-6, only differences are described in the following description.

Referring to FIG. 8, the attachment pressing apparatus 500 may include two or more units. In the following description, for convenience of explanation, an embodiment in which the attachment pressing apparatus 500 includes three units is described. The three units may be arranged in a direction, for example, an x direction of FIG. 8.

In an embodiment, the attachment pressing apparatus 500 may include a first unit 500A, a second unit 500B, and a third unit 5000. As described above with reference to FIG. 7, in an embodiment, the wing plate 521 may be integrally formed across the first unit 500A to the third unit 5000, or in an embodiment, the wing plate 521 may be separated formed for each of the first unit 500A to the third unit 5000. For example, the wing plate 521 may include a first wing plate 521A, a second wing plate 521B, and a third wing plate 521C respectively arranged in the first unit 500A, the second unit 500B, and the third unit 5000. The first wing plate 521A, the second wing plate 521B, and the third wing plate 521C may be attachable and detachable with one another. As the first wing plate 521A, the second wing plate 521B, and the third wing plate 521C are similar to one another, in the following description, the first wing plate 521A is described.

The first wing plate 521A may include a first protruding portion 521-1A at a side of the first wing plate 521A in a direction, for example, a direction in which units are arranged (the x direction of FIG. 8), and a first recess portion 521-2A at another side of first wing plate 521A. The first protruding portion 521-1A may be insertion-coupled with a second recess portion 521-2B of an adjacent unit, for example, the second unit 500B. For example, the first recess portion 521-2A may be insertion-coupled with a third protruding portion 521-1C of another adjacent unit, for example, the third unit 5000.

The first protruding portion 521-1A may have various shapes protruding outwardly from the first wing plate 521A to reinforce a fastening force with the second recess portion 521-2B. In an embodiment, the first protruding portion 521-1A may have a rectangular shape in a plan view, but the disclosure is not limited thereto, and in another embodiment, the first protruding portion 521-1A may have a semi-circular shape or a shape including unevenness around the perimeter.

The first recess portion 521-2A may have a concave shape corresponding to the shape of the first protruding portion 521-1A. The first recess portion 521-2A may have a size corresponding to or less than the shape of the first protruding portion 521-1A.

Accordingly, the attachment pressing apparatus 500 may connect multiple units by a method in which, for example, a protruding portion 521-1 of one unit (for example, the first unit 500A) is insertion-coupled to a recess portion 521-2 of another adjacent unit (for example, the second unit 500B). As multiple units may be readily attachable and detachable, the units may be readily assembled or disassembled as necessary.

Although the disclosure is described based on the embodiments illustrated in the drawings, the disclosure is not limited thereto.

According to embodiments, an attachment may always be attached to a member to which the attachment adheres, with a same pressing force, and accordingly, defects due to over-adhesion or weak adhesion in the attachment process may be prevented.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. An attachment pressing apparatus comprising:
a body portion that is tubular and extends in a first direction;
a wing portion connected to a side of the body portion in the first direction;
a pressing portion penetrating the wing portion in an inner space of the body portion in the first direction and pressing an attachment; and
a compression portion connecting another side of the body portion in the first direction and the pressing portion.

2. The attachment pressing apparatus of claim 1, wherein, in case that the wing portion moves toward the attachment, the compression portion is compressed and transfers a compressive force to the pressing portion, and the pressing portion presses the attachment.

3. The attachment pressing apparatus of claim 2, wherein the compression portion comprises a compression spring.

4. The attachment pressing apparatus of claim 1, wherein the wing portion comprises:
a wing plate including a through-hole through which the pressing portion passes and extending in a second direction intersecting the first direction; and
a leg extending from the wing plate to the attachment.

5. The attachment pressing apparatus of claim 4, wherein
the pressing portion includes a pressing surface contacting the attachment, and
in case that the wing portion moves until an end portion of the leg is located on a same plane as the pressing surface, the compression portion is compressed and presses the pressing portion.

6. The attachment pressing apparatus of claim 4, wherein the wing portion further comprises a length adjustment portion for adjusting a length of the leg.

7. The attachment pressing apparatus of claim 4, wherein in a plan view, a width of the wing plate in a direction is greater than a width of the wing plate in another direction perpendicular to the direction.

8. The attachment pressing apparatus of claim 1, wherein
the wing portion comprises:
a wing plate including a through-hole through which the pressing portion passes and extending in a second direction intersecting the first direction; and
a sliding guide portion that is tubular and extends from the wing plate to the compression portion, and
the sliding guide portion guides a movement of the wing portion along the pressing portion that is inserted to penetrate through a through-hole of the sliding guide portion.

9. The attachment pressing apparatus of claim 8, wherein
the pressing portion comprises:
a pressing plate in contact with the attachment;
a shaft connected to the pressing plate and penetrating the wing portion; and
a restriction portion arranged in an end portion of the shaft, and
a diameter of the restriction portion is greater than a diameter of the through-hole of the sliding guide portion.

10. The attachment pressing apparatus of claim 1, further comprising:
a measurement portion arranged at the another side of the body portion in the first direction, connected to the compression portion, and measuring a compressive force of the compression portion.

11. The attachment pressing apparatus of claim 10, further comprising:
a display portion arranged on an outer surface of the body portion and displaying the compressive force measured by the measurement portion.

12. An attachment pressing apparatus comprising:
a first unit and a second unit, wherein
each of the first unit and second unit comprises:
a body portion that is tubular and extends in a first direction;
a wing portion connected to a side of the body portion in the first direction;
a pressing portion penetrating the wing portion in an inner space of the body portion in the first direction and pressing an attachment; and
a compression portion connecting another side of the body portion in the first direction and the pressing portion, and
the wing portion of the first unit and the wing portion of the second unit are connected to each other.

13. The attachment pressing apparatus of claim 12, wherein, in case that the wing portion moves toward the attachment, the compression portion is compressed and transfers a compressive force to the pressing portion, and the pressing portion presses the attachment.

14. The attachment pressing apparatus of claim 12, wherein
the wing portion comprises:
a wing plate including a through-hole through which the pressing portion passes and extending in a second direction intersecting the first direction; and
a leg extending from the wing plate to the attachment, and
the wing plate of the first unit and the wing plate of the second unit are connected to each other.

15. The attachment pressing apparatus of claim 14, wherein the wing plate comprises:
a protruding portion protruding from a side of the wing plate; and
a concave recess portion arranged at another side of the wing plate and corresponding to a shape of the protruding portion.

16. The attachment pressing apparatus of claim 14, wherein
the pressing portion includes a pressing surface contacting the attachment, and
in case that the wing portion moves until an end portion of the leg is located on a same plane as the pressing surface, the compression portion is compressed and presses the pressing portion.

17. The attachment pressing apparatus of claim 14, wherein the wing portion further comprises a length adjustment portion for adjusting a length of the leg.

18. A method of manufacturing a display device, the method comprising:
attaching an adhesive chuck to a carrier by using an attachment pressing apparatus;
seating a display substrate on the carrier on which the adhesive chuck adheres; and
transferring a display substrate to a deposition device as the carrier moves,
wherein the attachment pressing apparatus comprises:
a body portion that is tubular and extends in a first direction;
a wing portion connected to a side of the body portion in the first direction and extending in a second direction intersecting the first direction;
a pressing portion penetrating the wing portion in an inner space of the body portion in the first direction and pressing the adhesive chuck; and
a compression portion connecting another side of the body portion in the first direction and the pressing portion.
